(19) United States
(12) Patent Application Publication
(10) Pub. No.: US 2013/0277091 A1
(43) Pub. Date: Oct. 24, 2013

(54) ELECTRODE STRUCTURE OF CAPACITIVE TOUCH PANEL

(71) Applicant: NOVATEK MICROELECTRONICS CORP., Hsinchu (TW)

(72) Inventors: Chun-Chieh Chang, Hsinchu City (TW); Chih-Chang Lai, Taichung City (TW); Chih-Peng Hsia, Hsinchu County (TW)

(73) Assignee: Novatek Microelectronics Corp., Hsinchu (TW)

(21) Appl. No.: 13/865,982

(22) Filed: Apr. 18, 2013

(30) Foreign Application Priority Data
Apr. 24, 2012 (TW) 101114578

(51) Int. Cl. H05K 1/02

(52) U.S. Cl. CPC H05K 1/0296
USPC 174/250

(57) ABSTRACT

An electrode structure of a capacitive touch panel including a plurality of receiving electrodes and driving electrodes is provided. Each of the receiving electrodes has at least one opening. Each of the driving electrodes includes a main region and a plurality of elongation regions. The area of each driving electrode is larger than that of each receiving electrode. Parts of the receiving electrodes surround a corresponding one of the driving electrodes, and the elongation regions of the surrounded driving electrode correspondingly stretch into the openings of the receiving electrodes which surround the driving electrode. By using the foregoing electrode structure, the capacitive touch panel is not only capable of providing sensing signals with less noise but is also capable of increasing input signals to enhance the signal to noise ratio.

### CROSS-REFERENCE TO RELATED APPLICATION

This application claims the priority benefit of Taiwan application serial no. 101114578, filed on Apr. 24, 2012. The entirety of the above-mentioned patent application is hereby incorporated by reference herein and made a part of this specification.

### BACKGROUND OF THE INVENTION

1. Field of the Invention

The invention relates to an electrode structure of a panel. Particularly, the invention relates to an electrode structure of a capacitive touch panel.

2. Description of Related Art

Along with development of a touch panel technique, the touch panels have been widely used on screens of electronic devices, for example, mobile phones, notebook computers or flat panel computers. The touch panel facilitates a user to conveniently perform an input operation, and a user interface thereof is more user-friendly and convenient.

Generally, an electrode structure of a capacitive touch panel includes a plurality of receiving electrodes and a plurality of driving electrodes. In an actual application, the driving electrodes are used to receive driving signals input through a panel controller, so as to drive the touch panel to sense a touch operation of the user. The receiving electrodes are used to generate sensing signals corresponding to the touch operations of the user. In the conventional technique, the receiving electrodes and the driving electrodes are generally designed to have the same shape and the same size. However, although a strong sensing signal can be generated according to such design, the larger an area of the receiving electrode is, the more noise is sensed.

### SUMMARY OF THE INVENTION

The invention is directed to an electrode structure of a capacitive touch panel, which is capable of increasing input signals while decreasing a noise of sensing signals, so as to enhance a signal to noise ratio.

The invention provides an electrode structure of a capacitive touch panel including a plurality of receiving electrodes and a plurality of driving electrodes. Each of the receiving electrodes has at least one opening. Each of the driving electrodes includes a main region and a plurality of elongation regions. An area of each of the driving electrodes is larger than that of each of the receiving electrodes. A part of the receiving electrodes surrounds a corresponding one of the driving electrodes, and the elongation regions of the surrounded driving electrode correspondingly stretch into the openings of the receiving electrodes that surround the driving electrode.

In an embodiment of the invention, regarding each of the receiving electrodes, a plurality of sides of the opening that are arranged along a same direction are substantially parallel.

In an embodiment of the invention, regarding each of the receiving electrodes, a plurality of sides of the receiving electrode that are arranged along a same direction are substantially parallel.

In an embodiment of the invention, regarding each of the receiving electrodes, a plurality of sides of the opening and the receiving electrode that are arranged along a same direction are substantially parallel.

In an embodiment of the invention, regarding each of the receiving electrodes, a plurality of sides of the opening and a plurality of sides of the receiving electrode form a first angle and a second angle. One of the first angle and the second angle is greater than another one.

In an embodiment of the invention, the electrode structure further includes a plurality of first electric bridges and a plurality of second electric bridges. The first electric bridges are coupled between the receiving electrodes. The second electric bridges are coupled between the driving electrodes. Regarding each of the receiving electrodes, compared to a smaller one of the first angle and the second angle, a greater one of the first angle and the second angle is closer to the second electric bridge corresponding to the surrounded driving electrode.

In an embodiment of the invention, regarding each of the receiving electrodes, compared to the smaller one of the first angle and the second angle, the greater one of the first angle and the second angle is away from the second electric bridge corresponding to the surrounded driving electrode.

In an embodiment of the invention, at least two of the openings of the receiving electrodes that surround the driving electrode open towards a same direction.

In an embodiment of the invention, at least two of the elongation regions of the surrounded driving electrode elongate towards a same direction.

In an embodiment of the invention, regarding each of the receiving electrodes, a plurality of sides of the opening and a plurality of sides of the receiving electrode form a first angle and a second angle. The first angle is substantially equal to the second angle.

In an embodiment of the invention, regarding each of the receiving electrodes, the first angle and the second angle are substantially 90 degrees.

In an embodiment of the invention, the openings of the receiving electrodes that surround the driving electrode open towards different directions.

In an embodiment of the invention, the elongation regions of the surrounded driving electrode elongate towards different directions.

In an embodiment of the invention, regarding each of the receiving electrodes, a plurality of sides of the opening form a third angle and a fourth angle at external of the receiving electrode, and the third angle and the fourth angle are substantially the same.

In an embodiment of the invention, regarding each of the receiving electrodes, the third angle and the fourth angle are substantially 90 degrees.

In an embodiment of the invention, regarding each of the receiving electrodes, a length of sides of the opening that are arranged along one direction is longer than a length of sides of the opening that are arranged along another direction.

In an embodiment of the invention, a plurality of sides of the receiving electrode that are arranged along a same direction are substantially parallel.

In an embodiment of the invention, a plurality of sides of the openings of the receiving electrodes surrounding the same driving electrode that are arranged along a same direction are substantially parallel.

In an embodiment of the invention, regarding each of the driving electrodes, a plurality of sides arranged along a same direction are substantially parallel.

In an embodiment of the invention, a plurality of sides of the driving electrodes that are arranged along a same direction are substantially parallel.

In an embodiment of the invention, profiles of the elongation regions of the surrounded driving electrode are conformal to profiles of the openings of the receiving electrodes that surround the driving electrode.

In an embodiment of the invention, regarding each of the driving electrodes, elongation lengths of the elongation regions relative to the driving electrode are substantially the same.

According to the above descriptions, an area of the receiving electrodes is decreased in a receiving area, so as to reduce the noise of the sensing signal. A coupling area of the driving electrodes and the receiving electrodes is increased at a driving area, so as to increase an intensity of an input signal and enhance a signal to noise ratio.

In order to make the aforementioned and other features and advantages of the invention comprehensible, several exemplary embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic diagram of an electrode structure of a capacitive touch panel.

FIG. 2A is a schematic diagram of an electrode structure of a capacitive touch panel according to an embodiment of the invention.

FIG. 2B and FIG. 2C are enlarged views of a part region of the electrode structure of FIG. 2A.

FIG. 3 is a schematic diagram of the electrode structure of FIG. 2A implemented on a capacitive touch panel.

FIG. 4A is a schematic diagram of an electrode structure of a capacitive touch panel according to an embodiment of the invention.

FIG. 4B and FIG. 4C are enlarged views of a part region of the electrode structure of FIG. 4A.

FIG. 5 is a schematic diagram of the electrode structure of FIG. 4A implemented on a capacitive touch panel.

FIG. 6A is schematic diagram of an electrode structure of a capacitive touch panel according to an embodiment of the invention.

FIG. 6B and FIG. 6C are enlarged views of a part region of the electrode structure of FIG. 6A.

FIG. 7 is a schematic diagram of the electrode structure of FIG. 6A implemented on a capacitive touch panel.

### DETAILED DESCRIPTION OF DISCLOSED EMBODIMENTS

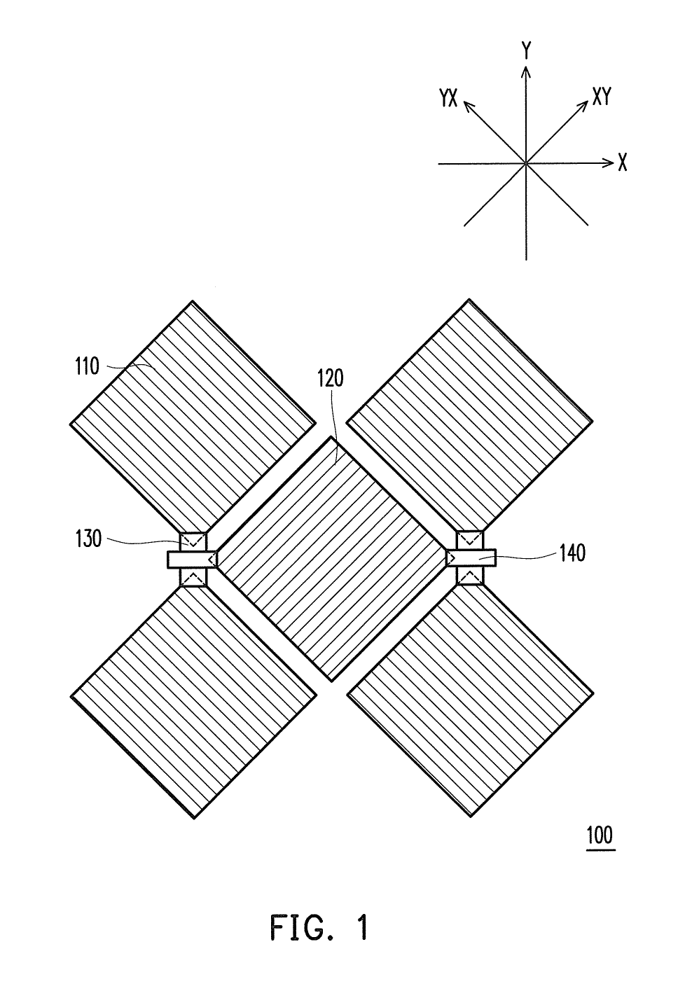

FIG. 1 is a schematic diagram of an electrode structure of a capacitive touch panel. Referring to FIG. 1, the electrode pattern 100 includes a plurality of receiving electrodes 110 arranged along a vertical direction and a plurality of driving electrodes 120 arranged along a horizontal direction, which requires a two-layer stacking structure or a single-layer structure for implementation. The electrode pattern 100 of the single layer structure requires vertical electric bridges 130 along the vertical direction to electrically connect the receiving electrodes 110 of the same column. The receiving electrodes 110 of a plurality of columns form a receiving area of the touch panel. Along the horizontal direction, the electrode pattern 100 requires horizontal electric bridges 140 to electrically connect the driving electrodes 120 of the same row. The driving electrodes 120 of a plurality of rows foam a driving area of the touch panel. In this example, the receiving electrodes and the driving electrodes are all diamond electrode structures with the same area.

### First Embodiment

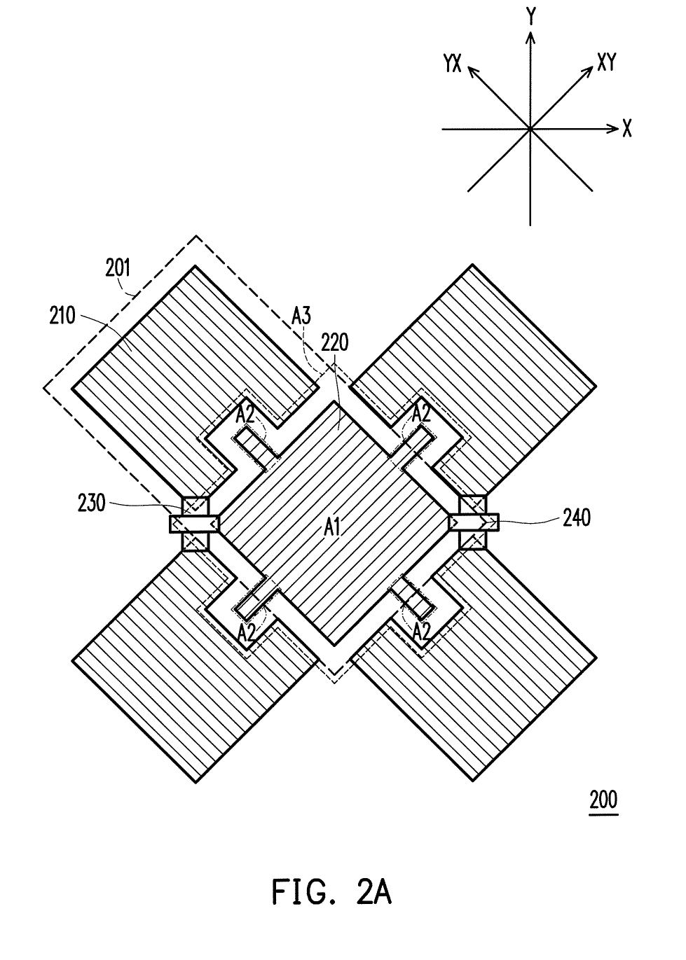

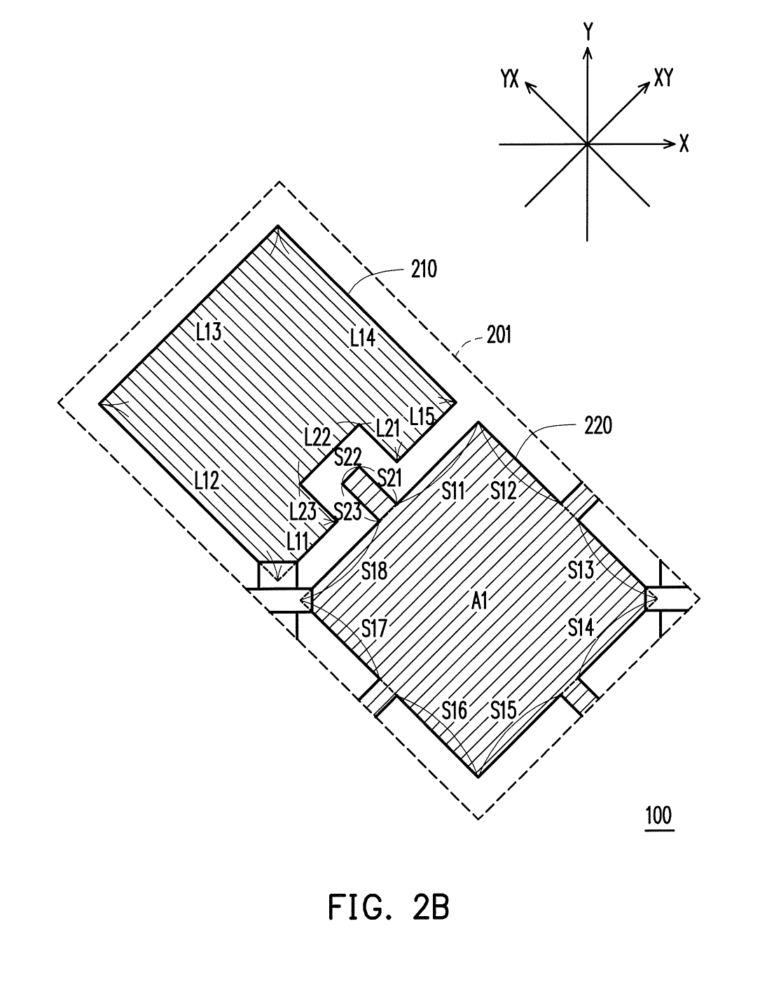

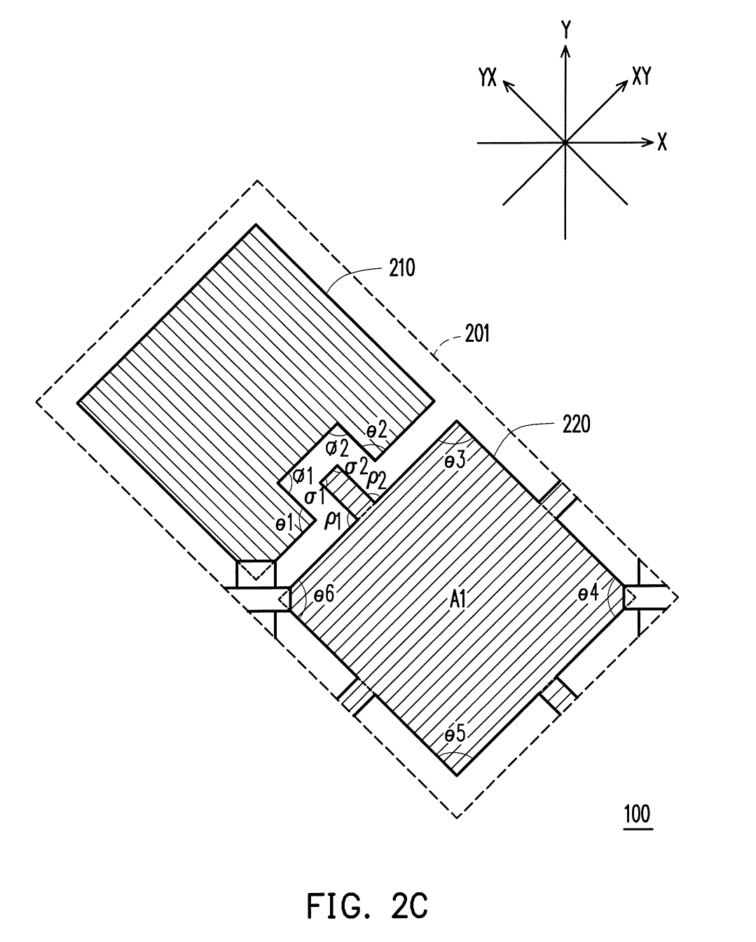

FIG. 2A is a schematic diagram of an electrode structure of a capacitive touch panel according to an embodiment of the invention, FIG. 2B and FIG. 2C are enlarged views of a part region of the electrode structure of FIG. 2A. Referring to FIG. 2A to FIG. 2C, the electrode pattern 200 of the touch panel of the present embodiment includes a plurality of receiving electrodes 210, a plurality of driving electrodes 220, a plurality of vertical electric bridges 230 and a plurality of horizontal electric bridges 240. The vertical electric bridges 230 are used to electrically connect the receiving electrodes 210 of a same column. The horizontal electric bridges 240 are used to electrically connect the driving electrodes 220 of a same row. In the present embodiment, the receiving electrodes 210 are isolated to the driving electrodes 220, and an area of each of the driving electrodes 220 is greater than an area of each of the receiving electrodes 210. Each of the receiving electrodes 210 has at least one opening. In the present embodiment, the opening of the top-left receiving electrode 210 refers to an area surrounded by a side group L21-L23, and the openings of the other receiving electrodes 210 can be deduced by analogy. Each of the driving electrodes 220 includes main region A1 and a plurality of elongation regions A2. The main region A1 has a quadrilateral electrode structure. Each of the elongation regions A2 has a rectangular electrode structure, though the invention is not limited thereto.

In the present embodiment, a part of the receiving electrodes 210 surrounds a corresponding one of the driving electrodes 220. Moreover, the elongation regions of the surrounded driving electrode 220 correspondingly stretch into the openings of the corresponding receiving electrodes 210. Here, the number of the receiving electrodes 210 that surround the driving electrode 220 is, for example, four, though the invention is not limited thereto. Moreover, a profile of each of the elongation regions A2 is conformal to a profile of the opening of the receiving electrode 210. Namely, a profile design of each of the elongation regions A2 is adjusted along with the profile of the corresponding opening to which the elongation region A2 stretches.

In detail, taking the top-left receiving circuit 210 of FIG. 2A as an example, it is a polygonal electrode structure, and includes an opening surrounded by the side group L21-L23. The polygonal electrode structure includes a plurality of sides L11-L15 and L21-L23. For simplicity's sake, the polygonal electrode structure is divided into two side sets. The side set L11-L15 is categorized as a plurality of sides of the receiving electrode 210, and the side set L21-L23 is categorized as a plurality of sides of the opening of the receiving electrode 210.

Regarding a boundary arrangement, referring to FIG. 2B, the receiving electrode 210 includes two sets of sides arranged along different directions XY and YX.

The sides of the two sets are substantially parallel along the respective arranging direction. For example, along the direction YX, the sides L11, L13 and L15 are substantially parallel, and along the direction XY, the sides L12 and L14 are substantially parallel. Moreover, the sides of the opening of the receiving electrode 210 that are arranged along the same direction are substantially parallel. Namely, the sides L21 and L23 arranged along the direction XY are substantially parallel. By observing the top-left receiving electrode 210 and the opening thereof, the sides thereof arranged along the same direction are also substantially parallel. For example, along the direction YX, the sides L11, L13, L15 and L22 are substantially parallel, and along the direction XY, the sides L12, L14, L21 and L23 are substantially parallel. Boundary relationships of the other receiving electrodes 210 and the openings thereof can be deduced by analogy, which are not described. In addition, by simultaneously observing the four receiving electrodes 210 of FIG. 2A, the sides of the four receiving electrodes 210 that are arranged along the same direction are also substantially parallel, as that shown in FIG. 2A. Moreover, by simultaneously observing the four openings of FIG. 2A, the sides of the four openings that are arranged along the same direction are also substantially parallel, as that shown in FIG. 2A.

In view of angles, referring to FIG. 2C, two angles θ1 and θ2 are respectively formed between the two sides L21 and L23 of the opening and the two sides L15 and L11 of the receiving electrode 210, and the two angles are substantially equal, though the invention is not limited thereto. In this example, the angles θ1 and θ2 are substantially 90 degrees. Moreover, regarding the opening, two angles φ1 and φ2 are respectively formed at external of the receiving electrode 210 between the sides L22 and L23 and between the sides L22 and L21, and the two angles φ1 and φ2 are substantially equal, though the invention is not limited thereto. In this example, the angles φ1 and φ2 are substantially 90 degrees.

In view of lengths of the sides of the opening, referring to FIG. 2B, a length of the sides of the opening of the receiving electrode 210 that are arranged along one direction is longer than a length of the side of the opening that is arranged along another direction. For example, the sides L21 and L23 of the opening that are arranged along one direction are longer than the side L22 of the opening that is arranged along another direction, though the invention is not limited thereto.

In view of opening directions, referring to FIG. 2A, the openings of the receiving electrode 210 open towards different directions. For example, the opening of the top-left receiving electrode 210 of FIG. 2A opens towards a direction −YX; the opening of the bottom-right receiving electrode 210 opens towards a direction +YX; the opening of the top-right receiving electrode 210 opens towards a direction −XY; and the opening of the bottom-left receiving electrode 210 opens towards a direction +XY. Therefore, at least in order to match the opening directions of the openings, the elongation regions A2 of the driving electrode 220 of the present embodiment also elongate towards different directions, as that shown in FIG. 2A.

In the present exemplary embodiment, regarding each of the receiving electrodes 210, each set of opposite sides of the polygonal electrode structure are substantially parallel, though the invention is not limited thereto. In other embodiments, the sides of each of the polygonal electrode structures that are arranged along a same direction can be unparallel. In the implementation pattern of unparallel sides, angles included by the sides of the polygonal electrode structure are also adjusted along with the structure variation, which is not limited by the invention.

In view of an area size, compared to the area of the diamond receiving electrode 110 of FIG. 1, the area of the receiving electrode 210 of the polygonal structure of the present embodiment is relatively small, so that the noise of the sensing signals thereof is reduced. Moreover, compared to the area of the driving electrode 220 of the present embodiment, the area of the receiving electrode 210 is relatively small.

On the other hand, taking one of the driving electrodes as an example, referring to FIG. 2A, the driving electrode 220 includes the main region A1 and a plurality of the elongation regions A2. The main region A1 has a quadrilateral electrode structure. Regarding the main region A1, in view of a boundary arrangement, referring to FIG. 2B, the quadrilateral electrode structure of the main region A1 includes two sets of sides arranged along different directions XY and YX. The sides of each set are substantially parallel along the respective arranging direction. For example, along the direction YX, the sides S11, S14, S15 and S18 are substantially parallel, and along the direction XY, the sides S12, S13, S16 and S17 are substantially parallel. In this example, lengths of the eight sides S11-S18 of the main region A1 can be substantially equivalent or different, which is not limited by the invention.

In view of the angles, referring to FIG. 2C, angles θ3 to 06 of the main region A1 are substantially equivalent or different, which is not limited by the invention. In the implementation pattern that the angles θ3 to 06 are equivalent, a magnitude thereof is substantially 90 degrees.

Regarding the elongation regions A2, referring to FIG. 2A, the driving electrodes 220 of the present embodiment includes four elongation regions A2 with substantially a same area. However, it should be noticed that the number of the elongation regions A2 and the area size thereof are not used to limit the invention. In this example, each of the elongation regions A2 is a rectangular electrode structure. In view of a boundary arrangement, referring to FIG. 2B, by individually observing one of the elongation regions A2, the sides thereof that are arranged along a same direction are substantially parallel. Namely, taking the top-left elongation region A2 of the driving electrode 220 as an example, the sides S21 and S23 arranged along the direction XY are substantially parallel. Moreover, the sides S21 and S23 of the elongation region A2 that are arranged along one direction are longer than the side S22 arranged along another direction, though the invention is not limited thereto. Moreover, referring to FIG. 2A, by observing the four elongation regions A2, the sides thereof that are arranged along a same direction are substantially parallel, which is not described in detail. Moreover, in this example, lengths of the different elongation regions A2 that elongate towards different directions can be substantially equivalent or different, which is not limited by the invention. In the present embodiment, taking the top-left elongation region A2 of the driving electrode 220 as an example, the elongation length thereof, for example, refers to a length of the side S21 or the side S23, i.e. a vertical distance between the side S22 and the side S11 or the side S18.

In view of the angles, referring to FIG. 2C, taking the top-left elongation region A2 of the driving electrode 220 as an example, two angles ρ 1 and ρ 1 are respectively formed at external of the driving electrode 220 between the two sides S21 and S23 of the elongation region A2 and the two sides S11 and S18 of the main region A1, and magnitudes of the two angles are substantially equivalent, though the invention is not limited thereto. In this example, the magnitudes of the angles ρ 1 and ρ 1 are substantially 90 degrees. Moreover, regarding the elongation region A2, two angles σ 1 and σ 2 are respectively formed between the side S22 and the other sides S23 and S21, and the two angles are substantially equivalent, though the invention is not limited thereto. In this example, the magnitudes of the angles σ 1 and σ 2 are substantially 90 degrees.

In view of an area size, compared to the area of the diamond driving electrode 120 of FIG. 1, the area of the driving electrode 220 of the polygonal structure of the present embodiment is larger, an the number of sides of the driving electrode 220 is relatively more, so that a coupling region A3 between the driving electrode 220 and the receiving electrodes 210 is larger. Such larger coupling area may effectively increase the intensity of the input signals, so as to enhance the signal to noise ratio. Moreover, the structure of the driving electrode 220 includes the main region A1 and the four elongation regions A2, so that compared to the area of the receiving electrode 210 of the present embodiment, the area of the driving electrode 220 is relatively large. Moreover, in the present exemplary embodiment, although the driving electrode 220 is divided into two parts of the main region A1 and the elongation regions A2, in an actual manufacturing process, the driving electrode 220 is a polygonal structure formed integrally, and is not fabricated separately in two parts.

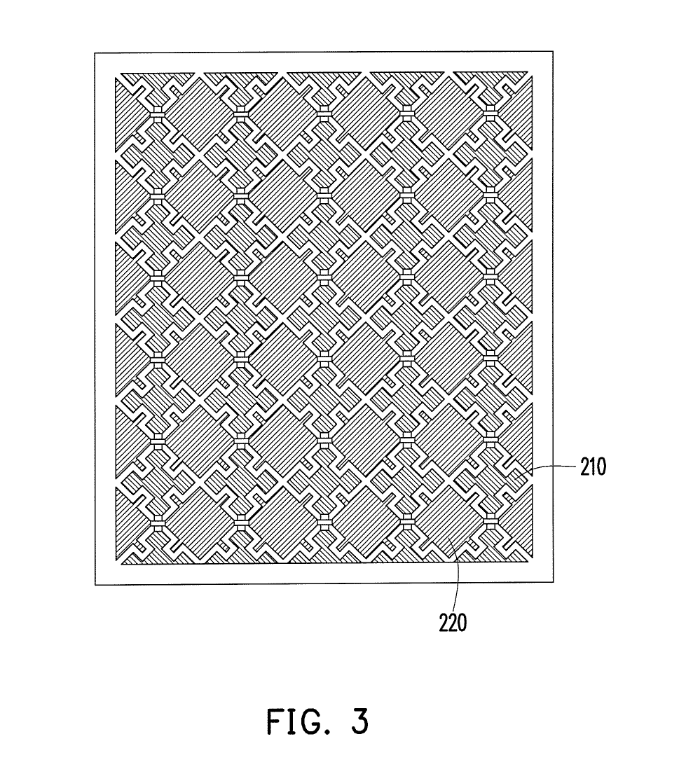

FIG. 3 is a schematic diagram of the electrode structure of FIG. 2A implemented on a capacitive touch panel. Referring to FIG. 3, FIG. 3 illustrates a capacitive touch panel with a set of 5×6 electrodes. The electrodes can be divided into two areas, which are respectively a driving area including a plurality of the driving electrodes 220 and a receiving area including a plurality of the receiving electrodes 210. In the driving area, 6 polygonal driving electrodes 220 of a same column are taken as an example for descriptions, and a geometric structure of each of the driving electrodes 220 is as that of the driving electrode 220 disclosed in the embodiment of FIG. 2A, which is not repeated herein. In the receiving area, 5 hexagonal receiving electrodes 210 of a same row are taken as an example for descriptions, the hexagonal geometric structure of each of the receiving electrodes 210 is as that of the receiving electrode 210 disclosed in the embodiment of FIG. 2A, which is not repeated herein. It should be noticed that the row and column are defined with reference of an array direction of FIG. 3, and the terms of row and column are not used to limit the invention. In the present embodiment, the driving electrode structure of the driving area includes the main region A1 and the four elongation regions A2, by which the coupling region A3 between the driving electrode 220 and the receiving electrodes 210 is increased, and the area of the receiving electrode structure of the receiving area is decreased to reduce the noise of the sensing signals.

### Second Embodiment

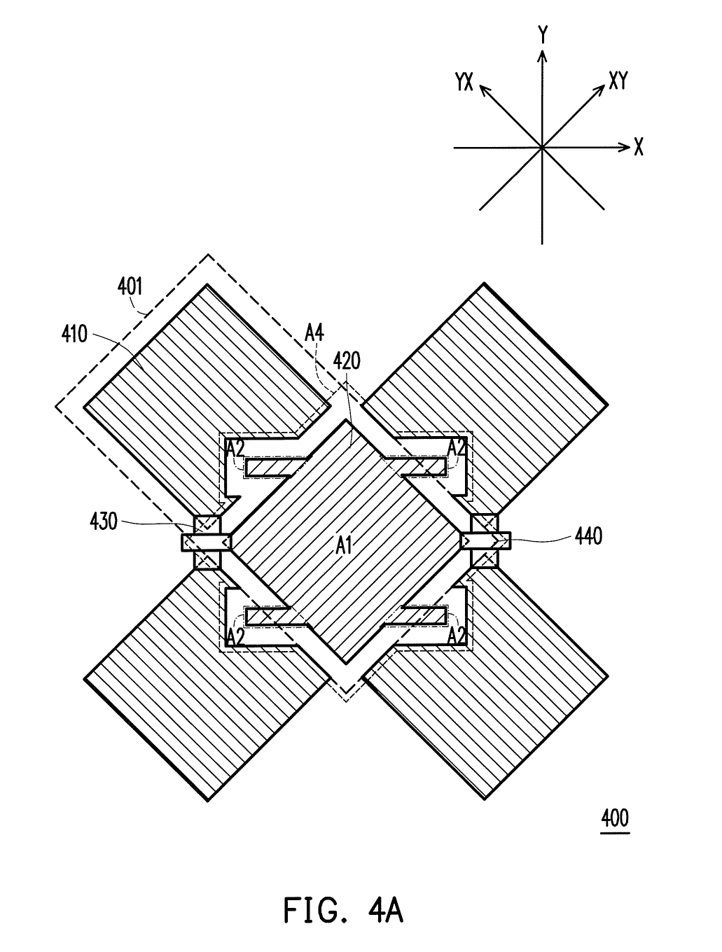

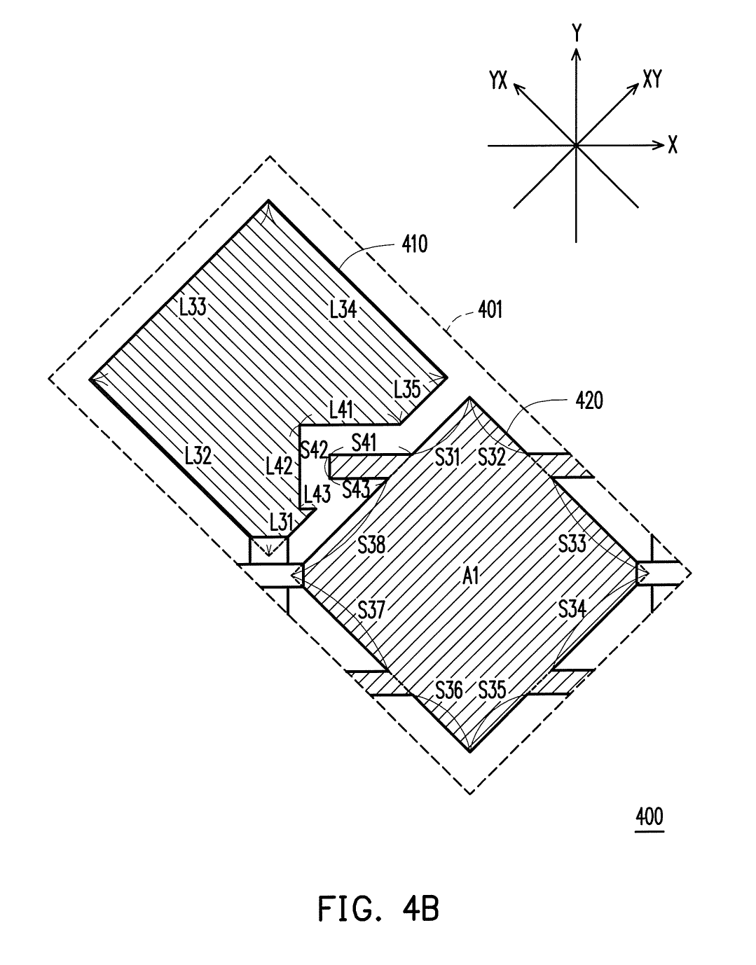

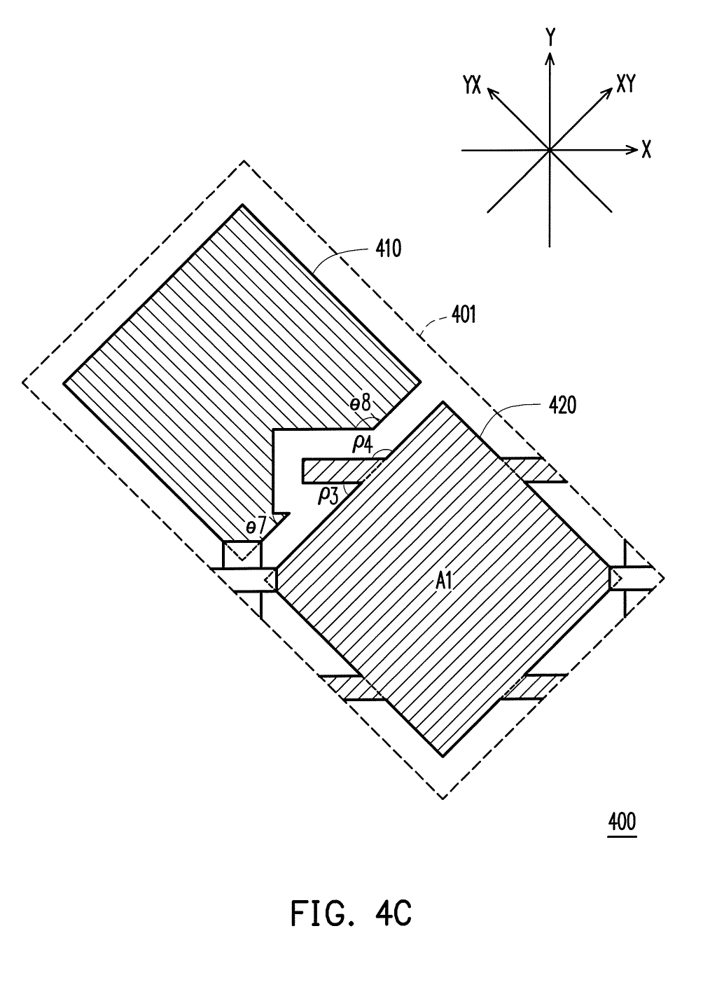

FIG. 4A is a schematic diagram of an electrode structure of a capacitive touch panel according to an embodiment of the invention, FIG. 4B and FIG. 4C are enlarged views of a part region of the electrode structure of FIG. 4A. Referring to FIG. 2A and FIG. 4A to FIG. 4C, the electrode pattern 400 of the touch panel of the present embodiment is similar to the electrode pattern 200 of the first embodiment, though a main difference there between lies in the opening directions of the openings of the receiving electrodes 410 and the elongation direction of the elongation regions A2 of the driving electrode 420. The main region A1 of the driving electrode 420 and the electrode structure of the receiving electrode 410 are as that of the main region A1 of the driving electrode 220 and the receiving electrode 210 of the first embodiment, so that details thereof are not repeated.

In detail, sizes of the four elongation regions A2 of the driving electrode 420 of the present embodiment are substantially equivalent, and at least two elongation regions A2 elongate towards a same direction. As shown in FIG. 4A, the two elongation regions A2 to the left of the driving electrode 420 elongate towards a direction −X, and the two elongation regions A2 to the right of the driving electrode 420 elongate towards a direction +X. Though it should be noticed that the left side and the right side of the present embodiment are only directions with reference of FIG. 4A, and the direction terms are not used to limit the invention.

In this example, since elongation manners of the four elongation regions A2 of the driving electrode 420 and the four elongation regions A2 of the driving electrode 220 are different, lengths of the sides S31 and S38 of the main region A1 of the driving electrode 420 are slightly adjusted according to an actual design. Moreover, since the top-left elongation region A2 of the driving circuit 420 elongates towards the direction −X, angles ρ 3 and ρ 4 formed between the elongation region A2 and the main region A1 are also slightly adjusted according to the actual design, and in this example, the angle ρ 4 is greater than the angle ρ 3. Namely, the angle ρ 3 closer to an electric bridge 440 is relatively small. Regarding pattern designs of the elongation regions A2 of the other driving electrodes 420 in FIG. 4A, geometric relationship of the angles and the boundary thereof can be deduced by analogy, which are not repeated. Moreover, in the present embodiment, lengths of the different elongation regions A2 that elongate towards different directions can be substantially equivalent or different, which is not limited by the invention. In the present embodiment, taking the top-left elongation region A2 of the driving electrode 420 as an example, the elongation length thereof is, for example, a length of the longer side S41.

At least in order to match the elongation directions of the elongation regions A2 of the driving electrode 420, the opening directions of the openings of the receiving electrodes 410 of the present embodiment are also slightly adjusted according to an actual design. As shown in FIG. 4A, the openings of the two receiving electrodes 410 at the left side open towards the direction +X, and the openings of the two receiving electrodes 410 at the right side open towards the direction −X to facilitate the elongation regions A2 of the driving electrode 420 to correspondingly stretch in. Namely, at least two of the openings of the receiving electrodes 410 that surround the driving electrode 420 open towards a same direction. In an implementation of the invention, a profile of each of the elongation regions A2 is conformal to a profile of the opening of the receiving electrode 410, though the invention is not limited thereto.

In view of the angles, referring to FIG. 4C, taking the opening of the top-left receiving electrode 410 as an example, since such opening opens towards the direction +X, angles θ7 and θ8 formed between the opening and the receiving electrode 410 are also slightly adjusted according to the actual design, and in this example, the angle θ8 is greater than the angle θ7. In the present embodiment, compared to the angle θ7, the larger angle θ8 is away from the electric bridge 440 located to the left the driving electrode 420. Regarding pattern designs of the openings of the other receiving electrodes 410 in FIG. 4A, geometric relationship of the angles and the boundary thereof can be deduced by analogy, which are not repeated.

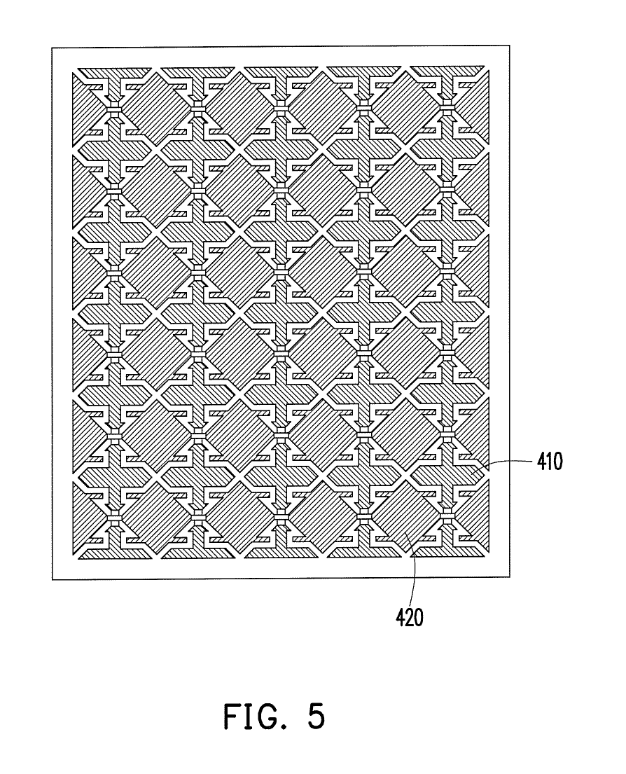

FIG. 5 is a schematic diagram of the electrode structure of FIG. 4A implemented on a capacitive touch panel. Referring to FIG. 5, FIG. 5 illustrates a capacitive touch panel with a set of 5×6 electrodes. The electrodes can be divided into two areas, which are respectively a driving area including a plurality of the driving electrodes 420 and a receiving area including a plurality of the receiving electrodes 410. In the driving area, 6 polygonal driving electrodes 420 of a same column are taken as an example for descriptions, and a geometric structure of each of the driving electrodes 420 is as that of the driving electrode 420 disclosed in the embodiment of FIG. 4A, which is not repeated herein. In the receiving area, 5 polygonal receiving electrodes 410 of a same row are taken as an example for descriptions, the hexagonal geometric structure of each of the receiving electrodes 410 is as that of the receiving electrode 410 disclosed in the embodiment of FIG. 4A, which is not repeated herein. It should be noticed that the row and column are defined with reference of an array direction of FIG. 5, and the terms of row and column are not used to limit the invention. In the present embodiment, the driving electrode structure of the driving area includes the main region A1 and the four elongation regions A2, by which the coupling region A4 between the driving electrode 420 and the receiving electrodes 410 is increased, and the area of the receiving electrode structure of the receiving area is decreased to reduce the noise of the sensing signals.

### Third Embodiment

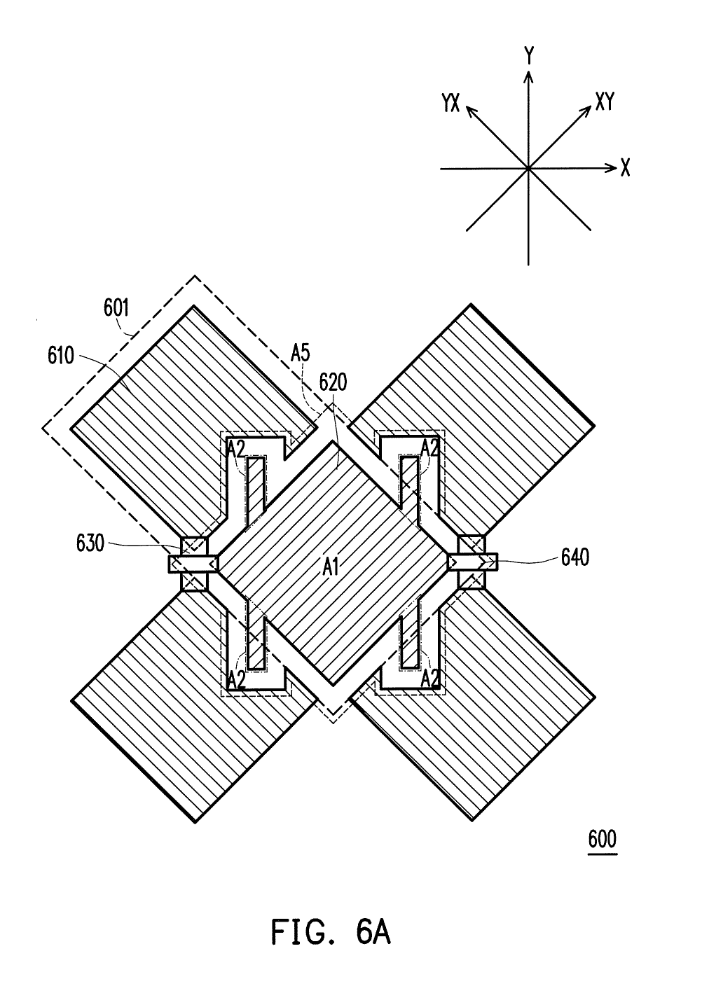

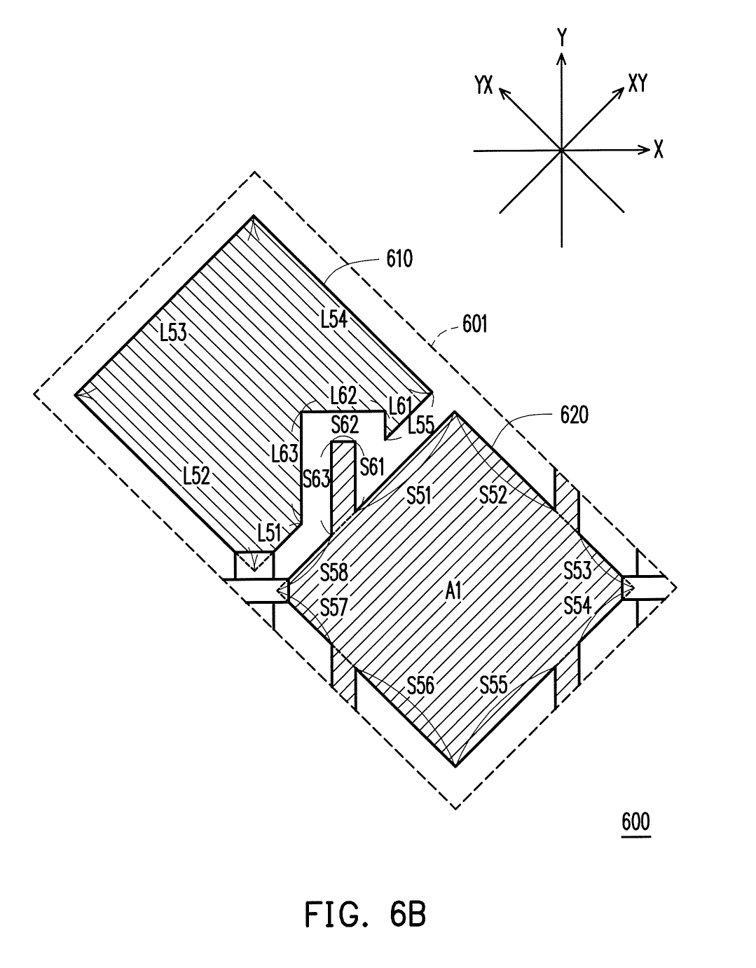

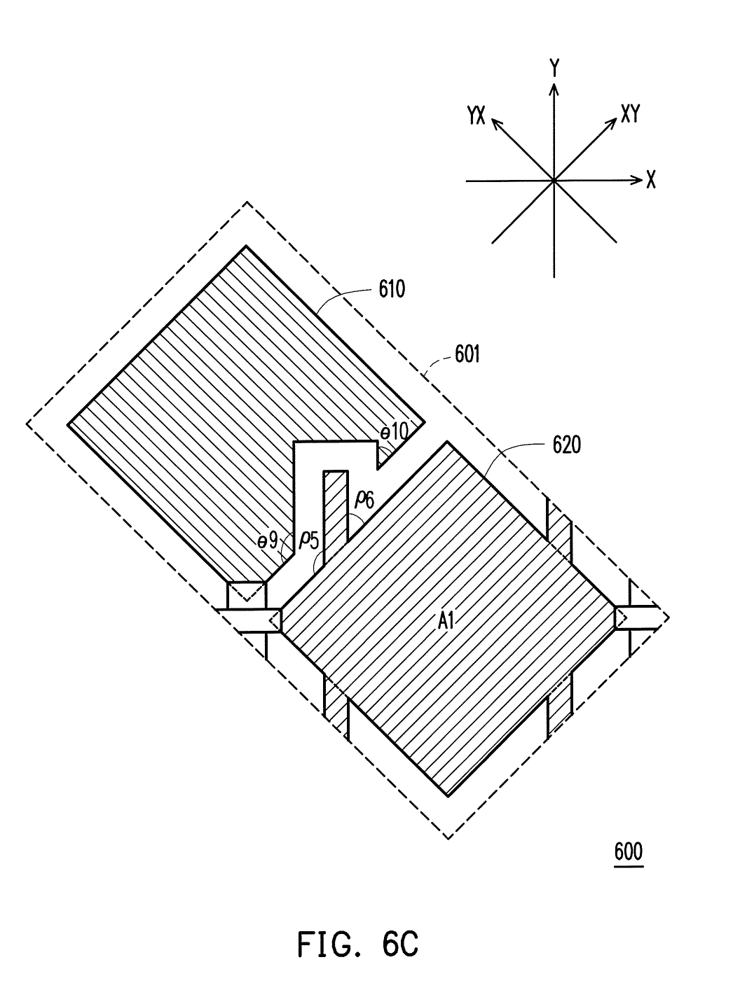

FIG. 6A is schematic diagram of an electrode structure of a capacitive touch panel according to an embodiment of the invention, FIG. 6B and FIG. 6C are enlarged views of a part region of the electrode structure of FIG. 6A. Referring to FIG. 2A and FIG. 6A to FIG. 6C, the electrode pattern 600 of the touch panel of the present embodiment is similar to the electrode pattern 200 of the first embodiment, though a main difference there between lies in the opening directions of the openings of the receiving electrodes 610 and the elongation direction of the elongation regions A2 of the driving electrode 620. The main region A1 of the driving electrode 620 and the electrode structure of the receiving electrode 610 are as that of the main region A1 of the driving electrode 220 and the receiving electrode 210 of the first embodiment, so that details thereof are not repeated.

In detail, sizes of the four elongation regions A2 of the driving electrode 620 of the present embodiment are substantially equivalent, and at least two elongation regions A2 elongate towards a same direction. As shown in FIG. 6A, the lower two elongation regions A2 of the driving electrode 620 elongate towards a direction −Y, and the upper two elongation regions A2 of the driving electrode 620 elongate towards a direction +Y. Though it should be noticed that the upper and lower sides of the present embodiment are only directions with reference of FIG. 6A, and the direction terms are not used to limit the invention.

In this example, since elongation manners of the four elongation regions A2 of the driving electrode 620 and the four elongation regions A2 of the driving electrode 220 are different, lengths of the sides S51 and S58 of the main region A1 of the driving electrode 620 are slightly adjusted according to an actual design. Moreover, taking the top-left elongation region A2 of the driving electrode 620 as an example, since the top-left elongation region A2 of the driving circuit 620 elongates towards the direction +Y, angles ρ 5 and ρ 6 formed between the elongation region A2 and the main region A1 are also slightly adjusted according to the actual design, and in this example, the angle ρ 6 is greater than the angle ρ 5. Namely, the angle ρ 5 closer to an electric bridge 640 is relatively large. Regarding pattern designs of the elongation regions A2 of the other driving electrodes 620 in FIG. 6A, geometric relationship of the angles and the boundary thereof can be deduced by analogy, which are not repeated. Moreover, in the present embodiment, lengths of the different elongation regions A2 that elongate towards different directions can be substantially equivalent or different, which is not limited by the invention. In the present embodiment, taking the top-left elongation region A2 of the driving electrode 620 as an example, the elongation length thereof is, for example, a length of the longer side S62.

At least in order to match the elongation directions of the elongation regions A2 of the driving electrode 620, the opening directions of the openings of the receiving electrodes 610 of the present embodiment are also slightly adjusted according to an actual design. As shown in FIG. 6A, the openings of the lower two receiving electrodes 610 open towards the direction +Y, and the openings of the upper two receiving electrodes 610 open towards the direction −Y to facilitate the elongation regions A2 of the driving electrode 620 to correspondingly stretch in. Namely, at least two of the openings of the receiving electrodes 610 that surround the driving electrode 620 open towards a same direction. In an implementation of the invention, a profile of each of the elongation regions A2 is conformal to a profile of the opening of the receiving electrode 610, though the invention is not limited thereto.

In view of the angles, referring to FIG. 6C, taking the opening of the top-left receiving electrode 610 as an example, since such opening opens towards the direction −Y, angles θ9 and θ10 formed between the opening and the receiving electrode 610 are also slightly adjusted according to the actual design, and in this example, the angle θ10 is smaller than the angle θ9. In the present embodiment, compared to the angle θ10, the larger angle θ9 is closer the electric bridge 640 located to the left the driving electrode 620. Regarding pattern designs of the openings of the other receiving electrodes 610 in FIG. 6A, geometric relationship of the angles and the boundary thereof can be deduced by analogy, which are not repeated.

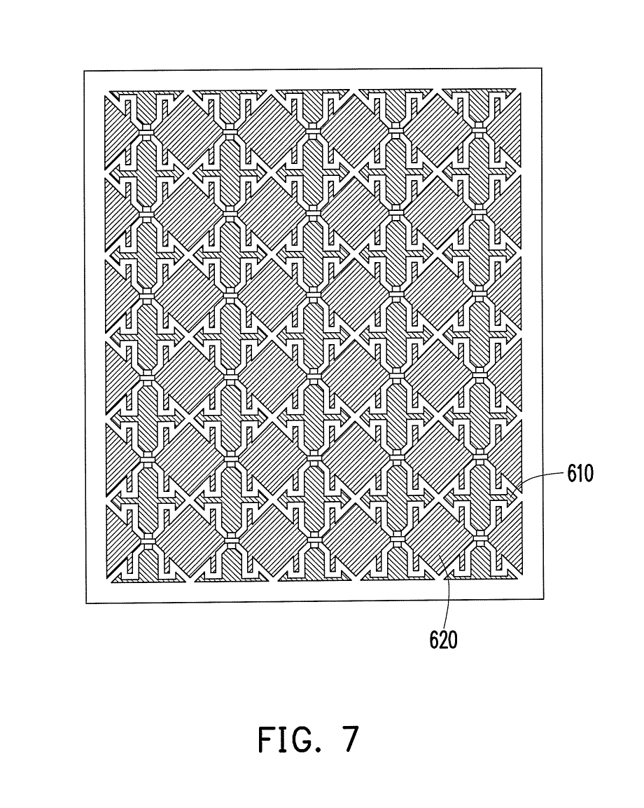

FIG. 7 is a schematic diagram of the electrode structure of FIG. 6A implemented on a capacitive touch panel. Referring to FIG. 7, FIG. 7 illustrates a capacitive touch panel with a set of 5×6 electrodes. The electrodes can be divided into two areas, which are respectively a driving area including a plurality of the driving electrodes 720 and a receiving area including a plurality of the receiving electrodes 710. In the driving area, 6 polygonal driving electrodes 620 of a same column are taken as an example for descriptions, and a geometric structure of each of the driving electrodes 620 is as that of the driving electrode 620 disclosed in the embodiment of FIG. 6A, which is not repeated herein. In the receiving area, 5 hexagonal receiving electrodes 610 of a same row are taken as an example for descriptions, the polygonal geometric structure of each of the receiving electrodes 610 is as that of the receiving electrode 610 disclosed in the embodiment of FIG. 6A, which is not repeated herein. It should be noticed that the row and column are defined with reference of an array direction of FIG. 7, and the terms of row and column are not used to limit the invention. In the present embodiment, the driving electrode structure of the driving area includes the main region A1 and the four elongation regions A2, by which the coupling region A5 between the driving electrode 620 and the receiving electrodes 610 is increased, and the area of the receiving electrode structure of the receiving area is decreased to reduce the noise of the sensing signals.

In summary, an area of the receiving electrodes is decreased in a receiving area, so as to reduce the noise of the sensing signals. A coupling area of the driving electrodes and the receiving electrodes is increased at a driving area, so as to increase an intensity of an input signal and enhance a signal to noise ratio. In the exemplary embodiments of the invention, the method of increasing the coupling area includes adding the elongation regions of the driving electrode and configuring the openings of the receiving electrodes, and pattern designs of the elongation regions and the openings can be adjusted according to the actual design.

It will be apparent to those skilled in the art that various modifications and variations can be made to the structure of the invention without departing from the scope or spirit of the invention. In view of the foregoing, it is intended that the invention cover modifications and variations of this invention provided they fall within the scope of the following claims and their equivalents.

What is claimed is:

1. An electrode structure of a capacitive touch panel, comprising:
a plurality of receiving electrodes, each having at least one opening; and
a plurality of driving electrodes, each comprising a main region and a plurality of elongation regions, wherein an area of each of the driving electrodes is larger than that of each of the receiving electrodes,
wherein a part of the receiving electrodes surrounds a corresponding one of the driving electrodes, and the elongation regions of the surrounded driving electrode correspondingly stretch into the openings of the receiving electrodes that surround the driving electrode.

2. The electrode structure as claimed in claim 1, wherein regarding each of the receiving electrodes, a plurality of sides of the opening that are arranged along a same direction are substantially parallel.

3. The electrode structure as claimed in claim 1, wherein regarding each of the receiving electrodes, a plurality of sides of the receiving electrode that are arranged along a same direction are substantially parallel.

4. The electrode structure as claimed in claim 1, wherein regarding each of the receiving electrodes, a plurality of sides of the opening and the receiving electrode that are arranged along a same direction are substantially parallel.

5. The electrode structure as claimed in claim 1, wherein regarding each of the receiving electrodes, a plurality of sides of the opening and a plurality of sides of the receiving electrode form a first angle and a second angle, and one of the first angle and the second angle is greater than another one.

6. The electrode structure as claimed in claim 5, further comprising:
a plurality of first electric bridges, coupled between the receiving electrodes; and
a plurality of second electric bridges, coupled between the driving electrodes,
wherein regarding each of the receiving electrodes, compared to a smaller one of the first angle and the second angle, a greater one of the first angle and the second angle is closer to the second electric bridge corresponding to the surrounded driving electrode.

7. The electrode structure as claimed in claim 5, further comprising:
a plurality of first electric bridges, coupled between the receiving electrodes; and
a plurality of second electric bridges, coupled between the driving electrodes,
regarding each of the receiving electrodes, compared to the smaller one of the first angle and the second angle, the greater one of the first angle and the second angle is away from the second electric bridge corresponding to the surrounded driving electrode.

8. The electrode structure as claimed in claim 5, wherein at least two of the openings of the receiving electrodes that surround the driving electrode open towards a same direction.

9. The electrode structure as claimed in claim 8, wherein at least two of the elongation regions of the surrounded driving electrode elongate towards a same direction.

10. The electrode structure as claimed in claim 1, wherein regarding each of the receiving electrodes, a plurality of sides of the opening and a plurality of sides of the receiving electrode form a first angle and a second angle, and the first angle is substantially equal to the second angle.

11. The electrode structure as claimed in claim 10, wherein regarding each of the receiving electrodes, the first angle and the second angle are substantially 90 degrees.

12. The electrode structure as claimed in claim 10, wherein the openings of the receiving electrodes that surround the driving electrode open towards different directions.

13. The electrode structure as claimed in claim 12, wherein the elongation regions of the surrounded driving electrode elongate towards different directions.

14. The electrode structure as claimed in claim 1, wherein regarding each of the receiving electrodes, a plurality of sides of the opening form a third angle and a fourth angle at external of the receiving electrode, and the third angle and the fourth angle are substantially the same.

15. The electrode structure as claimed in claim 14, wherein regarding each of the receiving electrodes, the third angle and the fourth angle are substantially 90 degrees.

16. The electrode structure as claimed in claim 1, wherein regarding each of the receiving electrodes, a length of sides of the opening that are arranged along one direction is longer than a length of sides of the opening that are arranged along another direction.

17. The electrode structure as claimed in claim 1, wherein a plurality of sides of the receiving electrode that are arranged along a same direction are substantially parallel.

18. The electrode structure as claimed in claim 1, wherein a plurality of sides of the openings of the receiving electrodes surrounding the same driving electrode that are arranged along a same direction are substantially parallel.

19. The electrode structure as claimed in claim 1, wherein regarding each of the driving electrodes, a plurality of sides arranged along a same direction are substantially parallel.

20. The electrode structure as claimed in claim 1, wherein a plurality of sides of the driving electrodes that are arranged along a same direction are substantially parallel.

21. The electrode structure as claimed in claim 1, wherein profiles of the elongation regions of the surrounded driving electrode are conformal to profiles of the openings of the receiving electrodes that surround the driving electrode.

22. The electrode structure as claimed in claim 1, wherein regarding each of the driving electrodes, elongation lengths of the elongation regions relative to the driving electrode are substantially the same.
